(19) United States
(12) Patent Application Publication
(10) Pub. No.: US 2021/0263815 A1
(43) Pub. Date: Aug. 26, 2021

(54) SEMICONDUCTOR DEVICES AND SEMICONDUCTOR SYSTEMS

(71) Applicant: SK hynix Inc., Icheon-si Gyeonggi-do (KR)

(72) Inventor: Dong Ho KANG, Seoul (KR)

(73) Assignee: SK hynix Inc., Icheon-si Gyeonggi-do (KR)

(21) Appl. No.: 16/995,252

(22) Filed: Aug. 17, 2020

(30) Foreign Application Priority Data
Feb. 26, 2020 (KR) 10-2020-0023719

(51) Int. Cl. G06F 11/20; G06F 3/06

(52) U.S. Cl. CPC G06F 11/2094; G06F 3/0619; G06F 2201/85; G06F 3/0673; G06F 3/0659

(57) ABSTRACT

A semiconductor device includes a core circuit and a repair circuit. The core circuit includes first and second memory regions and a repair region, each of which has columns that are selected by a first internal address, a second internal address, and a repair address. The core circuit receives or outputs data through columns that are selected by the first internal address, the second internal addresses, and the repair address. The repair circuit generates the first and second internal addresses by changing logic levels of first and second groups of addresses that are included in an address, generates the repair address from first and second failure addresses, and generates a selection signal to change an input/output (I/O) path of the data from the first and second failure addresses, in order to repair a failed column of the columns.

### CROSS-REFERENCE TO RELATED APPLICATIONS

The present application claims priority under 35 U.S.C 119(a) to Korean Application No. 10-2020-0023719, filed on Feb. 26, 2020, which is incorporated herein by reference in its entirety.

### BACKGROUND

### 1. Technical Field

Embodiments of the present disclosure relate to semiconductor devices repairing columns with a defective cell and semiconductor systems with the semiconductor devices.

### 2. Related Art

Attempts to increase the integration density in semiconductor devices have typically resulted in the increase of failed memory cells during the fabrication of the semiconductor devices. This may lead to the decrease in the fabrication yield of the semiconductor devices.

Even though each semiconductor device has a single defective memory cell, the semiconductor device cannot be supplied to customers.

A lot of effort has been focused on improving the fabrication yield of highly integrated semiconductor devices. For example, a repair technique using that uses fuses has been widely used to improve the fabrication yield of the highly integrated semiconductor devices.

According to the repair technique using with fuses, addresses of defective memory cells are stored by using the fuses. In such a case, if a column operation for the defective memory cell is performed, the defective memory cell may be replaced with a redundancy memory cell that corresponds to a normal memory cell.

### SUMMARY

According to an embodiment, a semiconductor device includes a core circuit and a repair circuit. The core circuit is configured to include first and second memory regions and a repair region, each of which has columns that are selected by a first internal address, a second internal address, and a repair address. The core circuit is configured to receive or output data through columns that are selected by the first internal address, the second internal addresses, and the repair address. The repair circuit is configured to generate the first and second internal addresses by changing logic levels of first and second groups of addresses that are included in an address, to generate the repair address from first and second failure addresses, and to generate a selection signal to change an input/output (I/O) path of the data from the first and second failure addresses, in order to repair a failed column of the columns.

According to another embodiment, a semiconductor device includes a core circuit and a repair circuit. The core circuit is configured to replace a first memory region with a failed column with any one of a second memory region and a repair region based on a first internal address, a second internal address, and a repair address to receive or output data. The repair circuit is configured to generate the first and second internal addresses by changing logic levels of first and second groups of addresses that are included in an address, to generate the repair address from first and second failure addresses, and to generate a selection signal to change an input/output (I/O) path of the data from the first and second failure addresses, in order to repair the failed column.

### BRIEF DESCRIPTION OF THE DRAWINGS

FIG. 1 is a block diagram, illustrating a configuration of a semiconductor system, according to an embodiment of the present disclosure.

FIG. 2 is a block diagram, illustrating a configuration of a semiconductor device, included in the semiconductor system that is illustrated in FIG. 1.

FIG. 3 is a block diagram, illustrating a configuration of a core circuit, included in the semiconductor device that is illustrated in FIG. 2.

FIG. 4 is a circuit diagram, illustrating a configuration of a data processing circuit, included in the core circuit that is illustrated in FIG. 3.

FIG. 5 is a block diagram, illustrating a configuration of a repair circuit, included in the semiconductor device that is illustrated in FIG. 2.

FIG. 6 is a block diagram, illustrating a configuration of a normal fuse circuit, included in the repair circuit that is illustrated in FIG. 5.

FIG. 7 illustrates a configuration of a first normal fuse circuit, included in the normal fuse circuit that is illustrated in FIG. 6.

FIGS. 8 to 12 illustrate a repair operation of a semiconductor system, according to an embodiment of the present disclosure.

FIG. 13 is a block diagram, illustrating a configuration of an electronic system, employing the semiconductor system that is illustrated in FIGS. 1 to 12.

### DETAILED DESCRIPTION OF THE EMBODIMENTS

It will be understood that although the terms “first”, “second”, “third” etc. are used herein to describe various elements, these elements should not be limited by these terms. These terms are only used to distinguish one element from another element. Thus, a first element in some embodiments could be termed a second element in other embodiments without departing from the teachings of the present disclosure or vice versa.

Further, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A logic “high” level and a logic “low” level may be used to describe logic levels of electric signals. A signal having a logic “high” level may be distinguished from a signal having a logic “low” level. For example, when a signal having a first voltage correspond to a signal having a logic “high” level, a signal having a second voltage correspond to a signal having a logic “low” level. In an embodiment, the logic “high” level may be set as a voltage level which is higher than a voltage level of the logic “low” level. Meanwhile, logic levels of signals may be set to be different or opposite according to the embodiments. For example, a certain signal having a logic “high” level in one embodiment may be set to have a logic “low” level in another embodiment.

Various embodiments of the present disclosure will be described hereinafter in detail with reference to the accompanying drawings. However, the embodiments described herein are for illustrative purposes only and are not intended to limit the scope of the present disclosure.

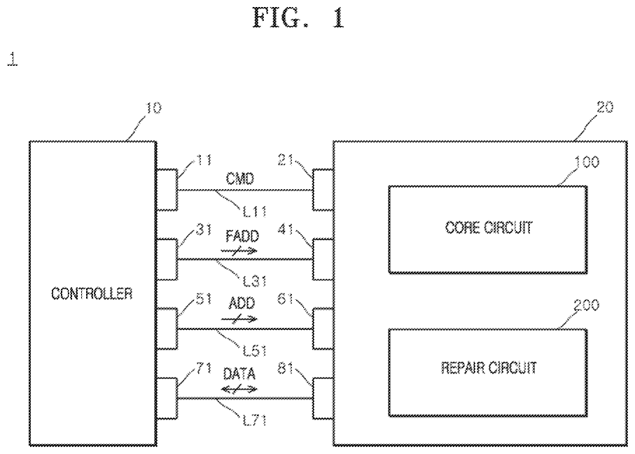

As illustrated in FIG. 1, a semiconductor system 1, according to an embodiment, may include a controller 10 and a semiconductor device 20. The semiconductor device 20 may include a core circuit 100 and a repair circuit 200.

The controller 10 may include a first control pin 11, a second control pin 31, a third control pin 51, and a fourth control pin 71. The semiconductor device 20 may include a first semiconductor pin 21, a second semiconductor pin 41, a third semiconductor pin 61, and a fourth semiconductor pin 81. The first control pin 11 and the first semiconductor pin 21 may be connected to each other by a first transmission line 11. The second control pin 31 and the second semiconductor pin 41 may be connected to each other by a second transmission line L31. The third control pin 51 and the third semiconductor pin 61 may be connected to each other by a third transmission line L51. The fourth control pin 71 and the fourth semiconductor pin 81 may be connected to each other by a fourth transmission line L71. The controller 10 may transmit a command AMD to the semiconductor device 20 through the first transmission line L11 to control the semiconductor device 20. The controller 10 may transmit a failure address FADD to the semiconductor device 20 through the second transmission line L31 to control the semiconductor device 20. The controller 10 may transmit an address ADD to the semiconductor device 20 through the third transmission line L51 to control the semiconductor device 20. The controller 10 may transmit data DATA to the semiconductor device 20 through the fourth transmission line L71 or may receive the data DATA from the semiconductor device 20 through the fourth transmission line L71.

The controller 10 may output the command CMD, the failure address FADD, and the address ADD to the semiconductor device 20 to perform a read operation of a column operation. The controller may receive the data DATA from the semiconductor device 20 during the read operation. The controller 10 may output the command CMD, the failure address FADD, the address ADD, and the data DATA to the semiconductor device 20 to perform a write operation of the column operation. The controller 10 may output the command CMD, the failure address FADD, the address ADD, and the data DATA to the semiconductor device 20 to perform a repair operation.

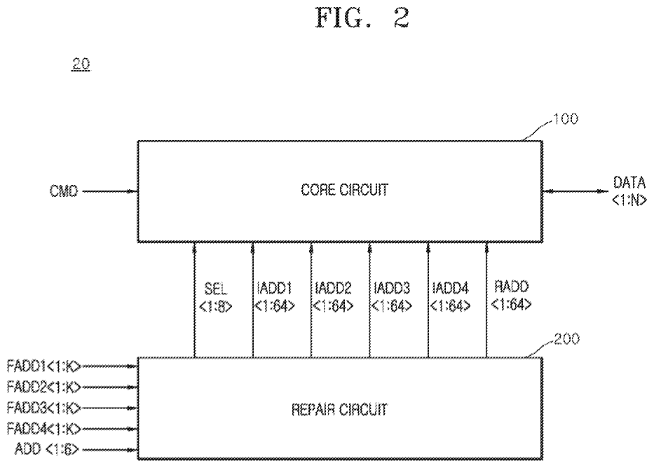

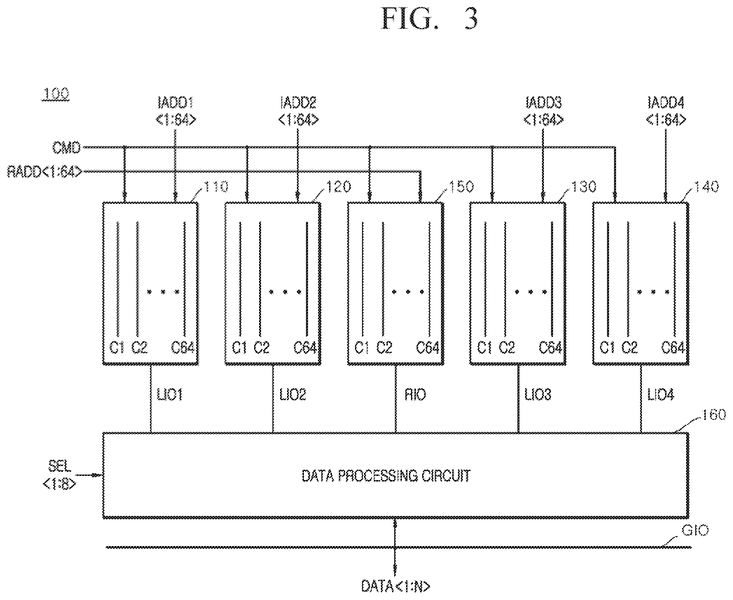

The core circuit 100 may include first to fourth memory regions (110, 120, 130, and 140 of FIG. 3) and a repair region (150 of FIG. 3) with columns that are selected by first to fourth internal addresses (IADD1<1:64>, IADD2<1:64>, IADD3<1:64>, and IADD4<1:64> of FIG. 2) and a repair address (RADD<1:64> of FIG. 2). The core circuit 100 may receive or output data (DATA<1:N> of FIG. 2) through the columns that are selected by the first to fourth internal addresses (IADD1<1:64>, IADD2<1:64>, IADD3<1:64>, and IADD4<1:64> of FIG. 2) and the repair address (RADD<1:64> of FIG. 2). The core circuit 100 may repair a memory region with a failed column by using any one of the first to fourth memory regions (110, 120, 130, and 140 of FIG. 3) and the repair region (150 of FIG. 3) based on the first to fourth internal addresses (IADD1<1:64>, IADD2<1:64>, IADD3<1:64>, and IADD4<1:64> of FIG. 2) and the repair address (RADD<1:64> of FIG. 2). For example, the core circuit 100 may repair a failed column that is included in any one of the first to fourth memory regions (110, 120, 130, and 140 of FIG. 3) by using a normal column that is included in any one of the first to fourth memory regions (110, 120, 130, and 140 of FIG. 3) and the repair region (150 of FIG. 3) based on the first to fourth internal addresses (IADD1<1:64>, IADD2<1:64>, IADD3<1:64>, and IADD4<1:64> of FIG. 2) and the repair address (RADD<1:64> of FIG. 2).

The repair circuit 200 may generate the first to fourth internal addresses (IADD1<1:64>, IADD2<1:64>, IADD3<1:64>, and IADD4<1:64> of FIG. 2) by changing the logic levels of first to eighth groups that are included in an address (ADD<1:6> of FIG. 2) to repair a failed column of the columns. The repair circuit 200 may generate the repair address (RADD<1:64> of FIG. 2) from first to fourth failure addresses (FADD1<1:K>, FADD2<1:K>, FADD3<1:K>, and FADD4<1:K> of FIG. 2). The repair circuit 200 may generate a selection signal (SEL<1:8> of FIG. 2) to change the path through which the data (DATA<1:N> of FIG. 2) is inputted or outputted.

FIG. 2 is a block diagram, illustrating a configuration of an example of the semiconductor device 20. As illustrated in FIG. 2, the semiconductor device 20 may include the core circuit 100 and the repair circuit 200.

The core circuit 100 may include the first to fourth memory regions (110, 120, 130, and 140 of FIG. 3) and the repair region (150 of FIG. 3), each of which has a plurality of columns. The core circuit 100 may receive or output the data DATA<1:N> through columns, which are selected by the command CMD, the first to fourth internal addresses IADD1<1:64>, IADD2<1:64>, IADD3<1:64>, and IADD4<1:64> and the repair address RADD<1:64>, among a plurality of columns that are included in the first to fourth memory regions (110, 120, 130, and 140 of FIG. 3) and the repair region (150 of FIG. 3). The core circuit 100 may output the data DATA<1:N> that is stored in columns that are selected by the command CMD, the first to fourth internal addresses IADD1<1:64>, IADD2<1:64>, IADD3<1:64>, and IADD4<1:64>, and the repair address RADD<1:64>, the columns being among a plurality of columns that are included in the first to fourth memory regions (110, 120, 130, and 140 of FIG. 3) and the repair region (150 of FIG. 3) during the read operation of the column operation. The core circuit 100 may store the data DATA<1:N> into columns that are selected by the command CMD, the first to fourth internal addresses IADD1<1:64>, IADD2<1:64>, IADD3<1:64>, and IADD4<1:64>, and the repair address RADD<1:64>, the columns being among a plurality of columns that are included in the first to fourth memory regions (110, 120, 130, and 140 of FIG. 3) and the repair region (150 of FIG. 3) during the write operation of the column operation. The core circuit 100 may replace a memory region, including a failed column, with any one of the first to fourth memory regions (110, 120, 130, and 140 of FIG. 3) and the repair region (150 of FIG. 3) in response to the command CMD, the first to fourth internal addresses IADD1<1:64>, IADD2<1:64>, IADD3<1:64>, and IADD4<1:64>, and the repair address RADD<1:64> during the read operation or the write operation of the column operation. For example, the core circuit 100 may replace a failed column that is included in any one of the first to fourth memory regions (110, 120, 130, and 140 of FIG. 3) with a normal column that is included in any one of the first to fourth memory regions (110, 120, 130, and 140 of FIG. 3) and the repair region (150 of FIG. 3) based on the command CMD, the first to fourth internal addresses IADD1<1:64>, IADD2<1:64>, IADD3<1:64>, and IADD4<1:64>, and the repair address RADD<1:64> during the read operation or the write operation of the column operation.

The repair circuit 200 may generate the first to fourth internal addresses IADD1<1:64>, IADD2<1:64>, IADD3<1:64>, and IADD4<1:64> from the address ADD<1:6> during the column operation. The repair circuit 200 may generate the first to fourth internal addresses IADD1<1:64>, IADD2<1:64>, IADD3<1:64>, and IADD4<1:64> by changing the logic levels of the first and second groups that are included in the address ADD<1:6> to repair a failed column, among the columns, during the column operation. The repair circuit 200 may generate the repair address RADD<1:64> from the first to fourth failure addresses FADD1<1:K>, FADD2<1:K>, FADD3<1:K>, and FADD4<1:K>. The repair circuit 200 may receive the first to fourth failure addresses FADD1<1:K>, FADD2<1:K>, FADD3<1:K>, and FADD4<1:K> to generate the selection signal SEL<1:8> (i.e., first to eighth selection signals) for changing a path through which the data DATA<1:N> are transmitted. The first to fourth failure addresses FADD1<1:K>, FADD2<1:K>, FADD3<1:K>, and FADD4<1:K> may include information on the locations of failed columns among the columns that are included in the first to fourth memory regions (110, 120, 130, and 140 of FIG. 3). The first and second groups that are included in the address ADD<1:6> will be described in detail later. The first failure address FADD1<1:K> may include the information on locations of failed columns that are included in the first memory region 110. The second failure address FADD2<1:K> may include information on the locations of failed columns that are included in the second memory region 120. The third failure address FADD3<1:K> may include information on locations of failed columns that are included in the third memory region 130. The fourth failure address FADD4<1:K> may include information on locations of failed columns that are included in the fourth memory region 140.

FIG. 3 is a block diagram illustrating a configuration of an example of the core circuit 100. As illustrated in FIG. 3, the core circuit 100 may include the first memory region 110, the second memory region 120, the third memory region 130, the fourth memory region 140, the repair region 150, and a data processing circuit 160.

The first memory region 110 may include first to sixty fourth columns C1˜C64, one of which is selected by the command CMD and the first internal address IADD1<1:64>. The first memory region 110 may electrically connect one of the first to sixty fourth columns C1˜C64, which is selected by the command CMD and the first internal address IADD1<1:64>, to a first local input/output (I/O) line LIO1. The first memory region 110 may output the data DATA<1:N> that is stored in memory cells (not shown) that are arrayed in one of the first to sixty fourth columns C1˜C64, which is selected by the command CMD and the first internal address IADD1<1:64>, to the first local I/O line LIO1 during the read operation of the column operation. The first memory region 110 may store the data DATA<1:N> that is loaded on the first local I/O line LIO1 into memory cells (not shown) that are arrayed in one of the first to sixty fourth columns C1˜C64, which is selected by the command CMD and the first internal address IADD1<1:64>, during the write operation of the column operation.

The second memory region 120 may also include first to sixty fourth columns C1˜C64, one of which is selected by the command CMD and the second internal address IADD2<1:64>. The second memory region 120 may electrically connect one of the first to sixty fourth columns C1˜C64, which is selected by the command CMD and the second internal address IADD2<1:64>, to a second local I/O line LIO2. The second memory region 120 may output the data DATA<1:N> that is stored in memory cells (not shown) that are arrayed in one of the first to sixty fourth columns C1˜C64, which is selected by the command CMD and the second internal address IADD2<1:64>, to the second local I/O line LIO2 during the read operation of the column operation. The second memory region 120 may store the data DATA<1:N> that is loaded on the second local I/O line LIO2 into memory cells (not shown) that are arrayed in one of the first to sixty fourth columns C1˜C64, which is selected by the command CMD and the second internal address IADD2<1:64>, during the write operation of the column operation.

The third memory region 130 may also include first to sixty fourth columns C1˜C64, one of which is selected by the command CMD and the third internal address IADD3<1:64>. The third memory region 130 may electrically connect one of the first to sixty fourth columns C1˜C64, which is selected by the command CMD and the third internal address IADD3<1:64>, to a third local I/O line L103. The third memory region 130 may output the data DATA<1:N> that is stored in memory cells (not shown) that are arrayed in one of the first to sixty fourth columns C1˜C64, which is selected by the command CMD and the third internal address IADD3<1:64>, to the third local I/O line LIO3 during the read operation of the column operation. The third memory region 130 may store the data DATA<1:N> that is loaded on the third local I/O line LIO3 into memory cells (not shown) that are arrayed in one of the first to sixty fourth columns C1˜C64, which is selected by the command CMD and the third internal address IADD3<1:64>, during the write operation of the column operation.

The fourth memory region 140 may also include first to sixty fourth columns C1˜C64, one of which is selected by the command CMD and the fourth internal address IADD4<1:64>. The fourth memory region 140 may electrically connect one of the first to sixty fourth columns C1˜C64, which is selected by the command CMD and the fourth internal address IADD4<1:64>, to a fourth local I/O line LIO4. The fourth memory region 140 may output the data DATA<1:N> that is stored in memory cells (not shown) that are arrayed in one of the first to sixty fourth columns C1˜C64, which is selected by the command CMD and the fourth internal address IADD4<1:64>, to the fourth local I/O line LIO4 during the read operation of the column operation. The fourth memory region 140 may store the data DATA<1:N> that is loaded on the fourth local I/O line LIO4 into memory cells (not shown) that are arrayed in one of the first to sixty fourth columns C1˜C64, which is selected by the command CMD and the fourth internal address IADD4<1:64>, during the write operation of the column operation.

The repair region 150 may also include first to sixty fourth columns C1˜C64, one of which is selected by the command CMD and the repair address RADD<1:64>. The repair region 150 may electrically connect one of the first to sixty fourth columns C1˜C64, which is selected by the command CMD and the repair address RADD<1:64>, to a repair I/O line RIO. The repair region 140 may output the data DATA<1:N> that is stored in memory cells (not shown) that are arrayed in one of the first to sixty fourth columns C1˜C64, which is selected by the command CMD and the repair address RADD<1:64>, to the repair I/O line RIO during the read operation of the column operation. The repair region 150 may store the data DATA<1:N> that is loaded on the repair I/O line RIO into memory cells (not shown) that are arrayed in one of the first to sixty fourth columns C1˜C64, which is selected by the command CMD and the repair address RADD<1:64>, during the write operation of the column operation.

The data processing circuit 160 may output or receive the data DATA<1:N> through a global I/O line GIO, the first local I/O line LIO1, the second local I/O line LIO2, the third local I/O line LIO3, the fourth local I/O line LIO4, and the repair I/O line RIO during the read operation or the write operation of the column operation. The data processing circuit 160 may output the data DATA<1:N> that is loaded on one, which is selected by the first to eighth selection signals SEL<1:8>, among the first local I/O line LIO1, the second local I/O line LIO2, the third local I/O line LIO3, the fourth local I/O line LIO4, and the repair I/O line RIO, to the global I/O line GIO during the read operation of the column operation. The data processing circuit 160 may transmit the data DATA<1:N> that is loaded on the global I/O line GIO to one, which is selected by the first to eighth selection signals SEL<1:8>, among the first local I/O line LIO1, the second local I/O line LIO2, the third local I/O line LIO3, the fourth local I/O line LIO4, and the repair I/O line RIO during the write operation of the column operation. Although FIG. 3 illustrates each of the global line I/O line GIO, the first local I/O line LIO1, the second local I/O line LIO2, the third local I/O line LIO3, the fourth local I/O line LIO4, and the repair I/O line RIO with a single line, each of the global line I/O line GIO, the first local I/O line LIO1, the second local I/O line LIO2, the third local I/O line LIO3, the fourth local I/O line LIO4, and the repair I/O line RIO may be configured to include a plurality of I/O lines. In such a case, the semiconductor device 20 may output or receive at least two data at a time.

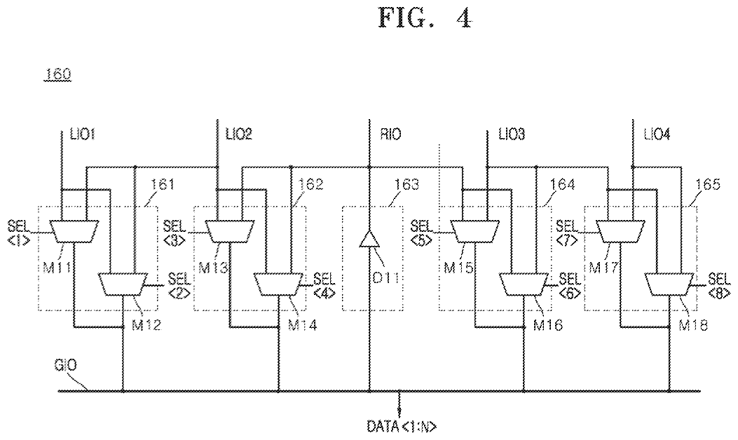

FIG. 4 is a circuit diagram, illustrating a configuration of an example of the data processing circuit 160. As illustrated in FIG. 4, the data processing circuit 160 may include a first data I/O circuit 161, a second data I/O circuit 162, a third data I/O circuit 163, a fourth data I/O circuit 164, and a fifth data I/O circuit 165.

The first data I/O circuit 161 may include a first data selection transmitter M11 and a second data selection transmitter M12. The first data selection transmitter M11 may output the data DATA<1:N> that is loaded on the first local I/O line LIO1 or the data DATA<1:N> that is loaded on the second local I/O line LIO2 to the global I/O line GIO based on a logic level of the first selection signal SEL<1> during the read operation. The second data selection transmitter M12 may output the data DATA<1:N> that is loaded on the global I/O line GIO to any one of the first local I/O line LIO1 and the second local I/O line LIO2 based on a logic level of the second selection signal SEL<2> during the write operation.

The second data I/O circuit 162 may include a third data selection transmitter M13 and a fourth data selection transmitter M14. The third data selection transmitter M13 may output the data DATA<1:N> that is loaded on the second local I/O line LIO2 or the data DATA<1:N> that is loaded on the repair I/O line RIO to the global I/O line GIO based on a logic level of the third selection signal SEL<3> during the read operation. The fourth data selection transmitter M14 may output the data DATA<1:N> that is loaded on the global I/O line GIO to any one of the second local I/O line LIO2 and the repair I/O line RIO based on a logic level of the fourth selection signal SEL<4> during the write operation.

The third data I/O circuit 163 may include a driver D11. The driver D11 may output the data DATA<1:N> that is loaded on the global I/O line GIO to the repair I/O line RIO during the write operation.

The fourth data I/O circuit 164 may include a fifth data selection transmitter M15 and a sixth data selection transmitter M16. The fifth data selection transmitter M15 may output the data DATA<1:N> that is loaded on the repair I/O line RIO or the data DATA<1:N> that is loaded on the third local I/O line LIO3 to the global I/O line GIO based on a logic level of the fifth selection signal SEL<5> during the read operation. The sixth data selection transmitter M16 may output the data DATA<1:N> that is loaded on the global I/O line GIO to any one of the repair I/O line RIO and the third local I/O line LIO3 based on a logic level of the sixth selection signal SEL<6> during the write operation.

The fifth data I/O circuit 165 may include a seventh data selection transmitter M17 and an eighth data selection transmitter M18. The seventh data selection transmitter M17 may output the data DATA<1:N> that is loaded on the third local I/O line LIO3 or the data DATA<1:N> that is loaded on the fourth local I/O line LIO4 to the global I/O line GIO based on a logic level of the seventh selection signal SEL<7> during the read operation. The eighth data selection transmitter M18 may output the data DATA<1:N> that is loaded on the global I/O line GIO to any one of the third local I/O line LIO3 and the fourth local I/O line LIO4 based on a logic level of the eighth selection signal SEL<8> during the write operation.

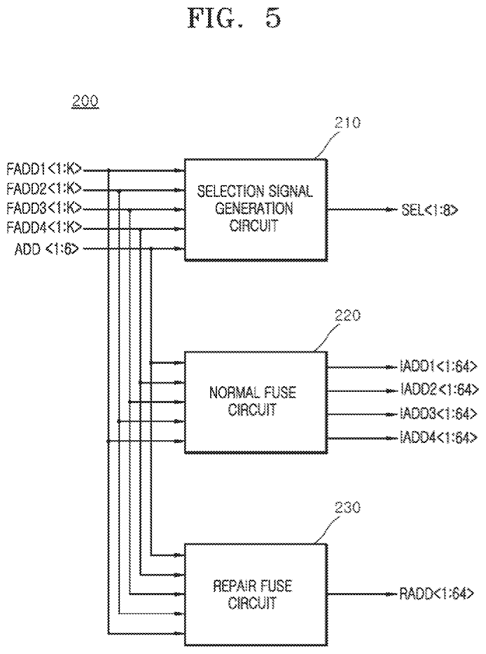

FIG. 5 is a block diagram, illustrating a configuration of an example of the repair circuit 200. As illustrated in FIG. 5, the repair circuit 200 may include a selection signal generation circuit 210, a normal fuse circuit 220, and a repair fuse circuit 230.

The selection signal generation circuit 210 may generate the first to eighth selection signals SEL<1:8> based on the first to fourth failure addresses FADD1<1:K>, FADD2<1:K>, FADD3<1:K>, and FADD4<1:K>. The selection signal generation circuit 210 may store the first to fourth failure addresses FADD1<1:K>, FADD2<1:K>, FADD3<1:K>, and FADD4<1:K>.

The selection signal generation circuit 210 may generate the first and second selection signals SEL<1:2> that change an I/O path of the data DATA<1:N> when the first failure address FADD1<1:K> has a logic level combination that selects a failed column among the first to sixty fourth columns C1˜C64 that are included in the first memory region 110. The selection signal generation circuit 210 may generate the third and fourth selection signals SEL<3:4> that change an I/O path of the data DATA<1:N> when the second failure address FADD2<1:K> has a logic level combination that selects a failed column among the first to sixty fourth columns C1˜C64 that are included in the second memory region 120. The selection signal generation circuit 210 may generate the fifth and sixth selection signals SEL<5:6> that change an I/O path of the data DATA<1:N> when the third failure address FADD3<1:K> has a logic level combination that selects a failed column among the first to sixty fourth columns C1˜C64 that are included in the third memory region 130. The selection signal generation circuit 210 may generate the seventh and eighth selection signals SEL<7:8> that change an I/O path of the data DATA<1:N> when the fourth failure address FADD4<1:K> has a logic level combination that selects a failed column among the first to sixty fourth columns C1˜C64 that are included in the fourth memory region 140.

The selection signal generation circuit 210 may generate the first and second selection signals SEL<1:2> that change an I/O path of the data DATA<1:N> when the address ADD<1:6> has a logic level combination that selects a failed column among the first to sixty fourth columns C1˜C64 that are included in the first memory region 110. The selection signal generation circuit 210 may generate the third and fourth selection signals SEL<3:4> that change an I/O path of the data DATA<1:N> when the address ADD<1:6> has a logic level combination that selects a failed column among the first to sixty fourth columns C1˜C64 that are included in the second memory region 120. The selection signal generation circuit 210 may generate the fifth and sixth selection signals SEL<5:6> that change an I/O path of the data DATA<1:N> when the address ADD<1:6> has a logic level combination that selects a failed column among the first to sixty fourth columns C1˜C64 that are included in the third memory region 130. The selection signal generation circuit 210 may generate the seventh and eighth selection signals SEL<7:8> that change an I/O path of the data DATA<1:N> when the address ADD<1:6> has a logic level combination that selects a failed column among the first to sixty fourth columns C1˜C64 that are included in the fourth memory region 140.

The normal fuse circuit 220 may decode the address ADD<1:6> to generate the first to fourth internal addresses IADD1<1:64>, IADD2<1:64>, IADD3<1:64>, and IADD4<1:64>. The normal fuse circuit 220 may compare the first to fourth failure addresses FADD1<1:K>, FADD2<1:K>, FADD3<1:K>, and FADD4<1:K> with the address ADD<1:6> and may change logic levels of the first and second groups that are included in the address ADD<1:6> based on the comparison result to generate the first to fourth internal addresses IADD1<1:64>, IADD2<1:64>, IADD3<1:64>, and IADD4<1:64>.

The repair fuse circuit 230 may store the first to fourth failure addresses FADD1<1:K>, FADD2<1:K>, FADD3<1:K>, and FADD4<1:K>. The repair fuse circuit 230 may compare the first to fourth failure addresses FADD1<1:K>, FADD2<1:K>, FADD3<1:K>, and FADD4<1:K> with the address ADD<1:6> and may generate the repair address RADD<1:64> based on the comparison result. The repair fuse circuit 230 may generate the repair address RADD<1:64> with a plurality of bit signals, one of which is selectively enabled when the address ADD<1:6> has a logic level combination that selects a failed column.

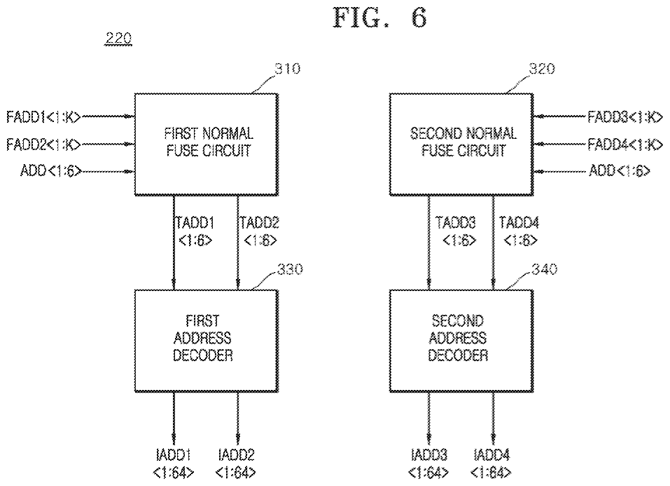

FIG. 6 is a block diagram illustrating a configuration of an example of the normal fuse circuit 220. As illustrated in FIG. 6, the normal fuse circuit 220 may include a first normal fuse circuit 310, a second normal fuse circuit 320, a first address decoder 330, and a second address decoder 340.

The first normal fuse circuit 310 may compare the first failure address FADD1<1:K> with the address ADD<1:6> and may change logic levels of a first group of address ADD<1:3> and a second group of address ADD<4:6> based on the comparison result to generate a first transfer address TADD1<1:6>. The first normal fuse circuit 310 may compare the second failure address FADD2<1:K> with the address ADD<1:6> and may change the logic levels of the first group of address ADD<1:3> and the second group of address ADD<4:6> based on the comparison result to generate a second transfer address TADD2<1:6>. The first normal fuse circuit 310 may change the logic levels of the first group of address ADD<1:3> and the second groups of address ADD<4:6> to generate the first transfer address TADD1<1:6> when some of the bits that are included in the first failure address FADD1<1:K> have the same logic level combination as the address ADD<1:6>. The bits of the first failure address FADD1<1:K> with the same logic level combination as the address ADD<1:6> that generate the first transfer address TADD1<1:6> may be set as bits that selects a failed column among the first to sixty fourth columns C1˜C64 that are included in the first memory region 110. The first normal fuse circuit 310 may change the logic levels of the first group of address ADD<1:3> and the second groups of address ADD<4:6> to generate the second transfer address TADD2<1:6> when some of the bits that are included in the second failure address FADD2<1:K> have the same logic level combination as the address ADD<1:6>. The bits of the second failure address FADD2<1:K> with the same logic level combination as the address ADD<1:6> that generate the second transfer address TADD2<1:6> may be set as bits that select a failed column among the first to sixty fourth columns C1˜C64 that are included in the second memory region 120. The first normal fuse circuit 310 may have a configuration that operates during the column operation for the first and second memory regions 110 and 120.

The second normal fuse circuit 320 may compare the third failure address FADD3<1:K> with the address ADD<1:6> and may change logic levels of the first group of address ADD<1:3> and the second group of address ADD<4:6> based on the comparison result to generate a third transfer address TADD3<1:6>. The second normal fuse circuit 320 may compare the fourth failure address FADD4<1:K> with the address ADD<1:6> and may change the logic levels of the first group of address ADD<1:3> and the second group of address ADD<4:6> based on the comparison result to generate a fourth transfer address TADD4<1:6>. The second normal fuse circuit 320 may change the logic levels of the first group of address ADD<1:3> and the second groups of address ADD<4:6> to generate the third transfer address TADD3<1:6> when some of the bits that are included in the third failure address FADD3<1:K> have the same logic level combination as the address ADD<1:6>. The bits of the third failure address FADD3<1:K> with the same logic level combination as the address ADD<1:6> that generate the third transfer address TADD3<1:6> may be set as bits that select a failed column among the first to sixty fourth columns C1˜C64 that are included in the third memory region 130. The second normal fuse circuit 320 may change the logic levels of the first group of address ADD<1:3> and the second groups of address ADD<4:6> to generate the fourth transfer address TADD4<1:6> when some of the bits that are included in the fourth failure address FADD4<1:K> have the same logic level combination as the address ADD<1:6>. The bits of the fourth failure address FADD4<1:K> with the same logic level combination as the address ADD<1:6> that generate the fourth transfer address TADD4<1:6> may be set as bits that select a failed column among the first to sixty fourth columns C1˜C64 that are included in the fourth memory region 140. The second normal fuse circuit 320 may have a configuration that operates during the column operation for the third and fourth memory regions 130 and 140.

The first address decoder 330 may generate the first internal address IADD1<1:64> based on the first transfer address TADD1<1:6>. The first address decoder 330 may decode the first transfer address TADD1<1:6> to generate the first internal address IADD1<1:64> with a plurality of bit signals, one of which is selectively enabled. The first address decoder 330 may generate the second internal address IADD2<1:64> from the second transfer address TADD2<1:6>. The first address decoder 330 may decode the second transfer address TADD2<1:6> to generate the second internal address IADD2<1:64> with a plurality of bit signals, one of which is selectively enabled.

The second address decoder 340 may generate the third internal address IADD3<1:64> from the third transfer address TADD3<1:6>. The second address decoder 340 may decode the third transfer address TADD3<1:6> to generate the third internal address IADD3<1:64> with a plurality of bit signals, one of which is selectively enabled. The second address decoder 340 may generate the fourth internal address IADD4<1:64> from the fourth transfer address TADD4<1:6>. The second address decoder 340 may decode the fourth transfer address TADD4<1:6> to generate the fourth internal address IADD4<1:64> with a plurality of bit signals, one of which is selectively enabled.

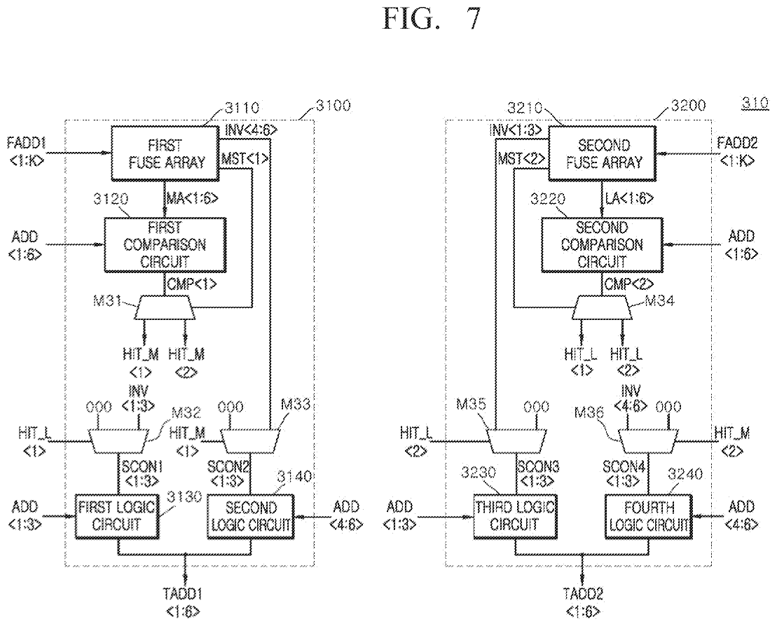

FIG. 7 is a block diagram, illustrating a configuration of an example of the first normal fuse circuit 310. As illustrated in FIG. 7, the first normal fuse circuit 310 may include a first address comparison circuit 3100 and a second address comparison circuit 3200.

The first address comparison circuit 3100 may include a first fuse array 3110, a first comparison circuit 3120, a first repair selection transmitter M31, a second repair selection transmitter M32, a third repair selection transmitter M33, a first logic circuit 3130, and a second logic circuit 3140.

The first fuse array 3110 may generate a first fuse address MA<1:6>, a first master signal MST<1>, and a second inversion control signal INV<4:6> from the first failure address FADD1<1:K>.

The first fuse array 3110 may generate the first fuse address MA<1:6> from a six-bit failure address to select a column in the first failure address FADD1<1:K>. The first fuse array 3110 may generate the first master signal MST<1> that is enabled to have a logic “low” level when the first failure address FADD1<1:K> has a logic level combination that selects a failed column that is included in the first memory region 110. The first fuse array 3110 may generate the first master signal MST<1> that is disabled to have a logic “high” level when the first failure address FADD1<1:K> does not have a logic level combination that selects a failed column that is included in the first memory region 110.

The first comparison circuit 3120 may compare the first fuse address MA<1:6> with the address ADD<1:6> to generate a first comparison signal CMP<1>. The first comparison circuit 3120 may generate the first comparison signal CMP<1>, which is enabled when the address ADD<1:6> and the first fuse address MA<1:6> have the same logic level combination.

The first repair selection transmitter M31 may output the first comparison signal CMP<1> as a first control signal HIT_M<1> when the first master signal MST<1> is disabled. The first repair selection transmitter M31 may output the first comparison signal CMP<1> as a second control signal HIT_M<2> when the first master signal MST<1> is enabled.

The second repair selection transmitter M32 may output a 3-bit signal with a logic level combination of ‘000’ or a first inversion control signal INV<1:3> as a first selection control signal SCON1<1:3> based on a third control signal HIT_L<1>.

The third repair selection transmitter M33 may output the 3-bit signal with a logic level combination of ‘000’ or the second inversion control signal INV<4:6> as a second selection control signal SCON2<1:3> based on the first control signal HIT_M<1>.

The first logic circuit 3130 may buffer the first group of address ADD<1:3> to generate first to third bit signals TADD1<1:3> of the first transfer address TADD1<1:6> when the first selection control signal SCON1<1:3> has a logic level combination of ‘000’.

The first logic circuit 3130 may inversely buffer a specific bit signal of the first group of address ADD<1:3> to generate the first to third bit signals TADD1<1:3> of the first transfer address TADD1<1:6> when the first selection control signal SCON1<1:3> is generated based on the first inversion control signal INV<1:3>. The specific bit signal of the first group of address ADD<1:3>, which is inverted by the first selection control signal SCON1<1:3>, may be set to be different based on the embodiments. For example, when the first bit signal SCON1<1> of the first selection control signal SCON1<1:3> is generated to have a logic “high” level, the first bit signal ADD<1> of the address ADD<1:6> may be inversely buffered.

The second logic circuit 3140 may buffer the second group of address ADD<4:6> to generate fourth to sixth bit signals TADD1<4:6> of the first transfer address TADD1<1:6> when the second selection control signal SCON2<1:3> has a logic level combination of ‘000’. The second logic circuit 3140 may inversely buffer a specific bit signal of the second group of address ADD<4:6> to generate the fourth to sixth bit signals TADD1<4:6> of the first transfer address TADD1<1:6> when the second selection control signal SCON2<1:3> is generated from the second inversion control signal INV<4:6>. The specific bit signal of the second group of address ADD<4:6>, which is inverted by the second selection control signal SCON2<1:3>, may be set to be different based on the embodiments. For example, when the first bit signal SCON2<1> of the second selection control signal SCON2<1:3> is generated to have a logic “high” level, the fourth bit signal ADD<4> of the address ADD<1:6> may be inversely buffered.

The second address comparison circuit 3200 may include a second fuse array 3210, a second comparison circuit 3220, a fourth repair selection transmitter M34, a fifth repair selection transmitter M35, a sixth repair selection transmitter M36, a third logic circuit 3230, and a fourth logic circuit 3240.

The second fuse array 3210 may generate a second fuse address LA<1:6>, a second master signal MST<2>, and the first inversion control signal INV<1:3> from the second failure address FADD2<1:K>. The second fuse array 3210 may generate the second fuse address LA<1:6> from a six-bit failure address to select a column in the second failure address FADD2<1:K>. The second fuse array 3210 may generate the second master signal MST<2> that is enabled to have a logic “low” level when the second failure address FADD2<1:K> has a logic level combination that selects a failed column that is included in the second memory region 120.

The second fuse array 3210 may generate the second master signal MST<2>, which is disabled to have a logic “high” level when the second failure address FADD2<1:K> does not have a logic level combination that selects a failed column that is included in the second memory region 120.

The second comparison circuit 3220 may compare the second fuse address LA<1:6> with the address ADD<1:6> to generate a second comparison signal CMP<2>. The second comparison circuit 3220 may generate the second comparison signal CMP<2> that is enabled when the address ADD<1:6> and the second fuse address LA<1:6> have the same logic level combination.

The fourth repair selection transmitter M34 may output the second comparison signal CMP<2> as the third control signal HIT_L<1> when the second master signal MST<2> is disabled. The fourth repair selection transmitter M34 may output the second comparison signal CMP<2> as a fourth control signal HIT_L<2> when the second master signal MST<2> is enabled.

The fifth repair selection transmitter M35 may output a 3-bit signal with a logic level combination of ‘000’ or the first inversion control signal INV<1:3> as a third selection control signal SCON3<1:3> based on the fourth control signal HIT_L<2>.

The sixth repair selection transmitter M36 may output the 3-bit signal with a logic level combination of ‘000’ or the second inversion control signal INV<4:6> as a fourth selection control signal SCON4<1:3> based on the second control signal HIT_M<2>.

The third logic circuit 3230 may buffer the first group of address ADD<1:3> to generate first to third bit signals TADD2<1:3> of the second transfer address TADD2<1:6> when the third selection control signal SCON3<1:3> has a logic level combination of ‘000’. The third logic circuit 3230 may inversely buffer a specific bit signal of the first group of address ADD<1:3> to generate the first to third bit signals TADD2<1:3> of the second transfer address TADD2<1:6> when the third selection control signal SCON3<1:3> is generated from the first inversion control signal INV<1:3>. The specific bit signal of the first group of address ADD<1:3>, which is inverted by the third selection control signal SCON3<1:3>, may be set to be different according to the embodiments. For example, when the first bit signal SCON3<1> of the third selection control signal SCON3<1:3> is generated to have a logic “high” level, the first bit signal ADD<1> of the address ADD<1:6> may be inversely buffered.

The fourth logic circuit 3240 may buffer the second group of address ADD<4:6> to generate fourth to sixth bit signals TADD2<4:6> of the second transfer address TADD2<1:6> when the fourth selection control signal SCON4<1:3> has a logic level combination of ‘000’. The fourth logic circuit 3240 may inversely buffer a specific bit signal of the second group of address ADD<4:6> to generate the fourth to sixth bit signals TADD2<4:6> of the second transfer address TADD2<1:6> when the fourth selection control signal SCON4<1:3> is generated from the second inversion control signal INV<4:6>. The specific bit signal of the second group of address ADD<4:6>, which is inverted by the fourth selection control signal SCON4<1:3>, may be set to be different according to the embodiments. For example, when the first bit signal SCON4<1> of the fourth selection control signal SCON4<1:3> is generated to have a logic “high” level, the fourth bit signal ADD<4> of the address ADD<1:6> may be inversely buffered.

The second normal fuse circuit 320, illustrated in FIG. 6, may be configured to have the same circuit as the first normal fuse circuit 310, illustrated in FIG. 7, except I/O signals thereof and may perform substantially the same operation as the first normal fuse circuit 310. Thus, detailed descriptions of the second normal fuse circuit 320 will be omitted hereinafter.

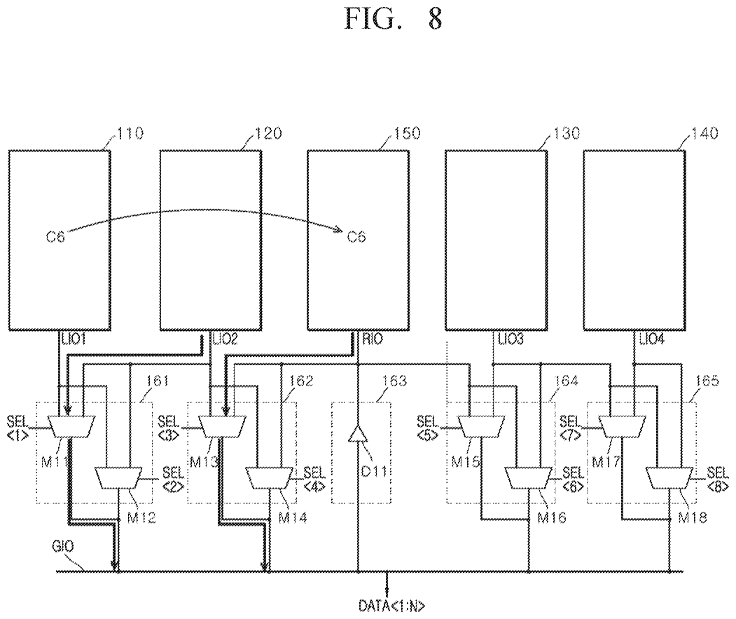

An operation of repairing a failed column and an operation of changing an I/O path of data, which are performed during the read operation of the column operation of the semiconductor system 1, will be described hereinafter with reference to FIGS. 8 to 10.

First, the repair operation and the data I/O path change operation will be described hereinafter with reference to FIG. 8 based on an embodiment in which the sixth column C6 of the first memory region 110 is a failed column.

The controller 10 may output the command CMD, the first failure address FADD1<1:K>, and the address ADD<1:6> for performing the read operation of the column operation to the semiconductor device 20. The address ADD<1:6> may have a logic level combination that selects the sixth column C6 of the first memory region 110.

The repair circuit 200 may generate the sixth bit signal RADD<6> of the repair address RADD<1:64> based on the first failure address FADD1<1:K>. The repair circuit 200 may generate the first selection signal SEL<1> and the third selection signal SEL<3> that are enabled by the first failure address FADD1<1:K>.

The repair region 150 may output the data DATA<1:N> stored in the sixth column C6, which is selected by the sixth bit signal RADD<6> of the repair address RADD<1:64>, to the repair I/O line RIO in response to the command CMD.

The first data I/O circuit 161 may connect the second local I/O line LIO2 to the global I/O line GIO based on the first selection signal SEL<1> that is enabled during the read operation. The second data I/O circuit 162 may connect the repair I/O line RIO to the global I/O line GIO based on the third selection signal SEL<3> that is enabled during the read operation.

The data processing circuit 160 may output the data DATA<1:N> that is loaded on the second local I/O line LIO2 and the repair I/O line RIO to the global I/O line GIO based on the first and third selection signals SEL<1> and SEL<3> during the read operation of the column operation.

As described above, the semiconductor system 1 may replace the sixth column C6 of the first memory region 110 with the sixth column C6 of the repair region 150 when the sixth column C6 of the first memory region 110 is a failed column.

In addition, the semiconductor system 1 may change an I/O path of the data DATA<1:N> from the first local I/O line LIO1 into the second local I/O line LIO2 when the sixth column C6 of the first memory region 110 is a failed column.

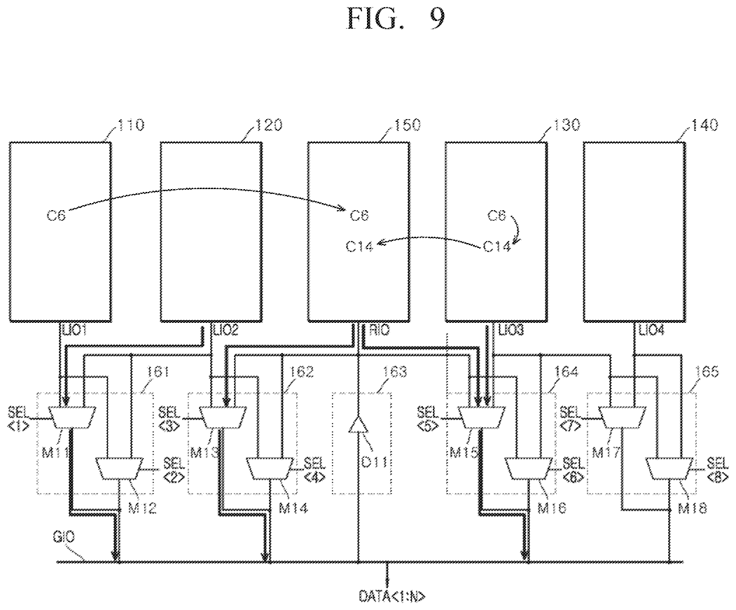

Next, the repair operation and the data I/O path change operation will be described hereinafter with reference to FIG. 9 based on an embodiment in which the sixth column C6 of the first memory region 110 and the sixth column C6 of the third memory region 130 are failed columns.

The controller 10 may output the command CMD, the first failure address FADD1<1:K>, the third failure address FADD3<1:K>, and the address ADD<1:6> for performing the read operation of the column operation to the semiconductor device 20. The address ADD<1:6> may have a logic level combination that selects the sixth column C6 of the first memory region 110 and the sixth column C6 of the third memory region 130.

The repair circuit 200 may generate the sixth bit signal RADD<6> of the repair address RADD<1:64> based on the first failure address FADD1<1:K>. The repair circuit 200 may generate the fourteenth bit signal RADD<14> of the repair address RADD<1:64> based on the third failure address FADD3<1:K>. The repair circuit 200 may invert the first group of address ADD<1:3> and the second group of address ADD<4:6> based on the third failure address FADD3<1:K> to generate the fourteenth bit signal IADD3<14> of the third internal address IADD3<1:64>. The repair circuit 200 may generate the first and third selection signals SEL<1> and SEL<3> that are enabled by the first and third failure addresses FADD1<1:K> and FADD3<1:K> and may generate the fifth selection signal SEL<5> that is disabled by the first and third failure addresses FADD1<1:K> and FADD3<1:K>.

The repair region 150 may output the data DATA<1:N> stored in the sixth column C6, which is selected by the sixth bit signal RADD<6> of the repair address RADD<1:64>, to the repair I/O line RIO in response to the command CMD. The repair region 150 may output the data DATA<1:N> stored in the fourteenth column C14, which is selected by the fourteenth bit signal RADD<14> of the repair address RADD<1:64>, to the repair I/O line RIO in response to the command CMD.

The first data I/O circuit 161 may connect the second local I/O line LIO2 to the global I/O line GIO based on the first selection signal SEL<1> that is enabled during the read operation. The second data I/O circuit 162 may connect the repair I/O line RIO to the global I/O line GIO based on the third selection signal SEL<3> that is enabled during the read operation. The fourth data I/O circuit 164 may connect the repair I/O line RIO to the global I/O line GIO based on the fifth selection signal SEL<5> that is disabled during the read operation.

The data processing circuit 160 may output the data DATA<1:N> that is loaded on the second local I/O line LIO2 and the repair I/O line RIO to the global I/O line GIO based on the first, third, and fifth selection signals SEL<1>, SEL<3>, and SEL<5> during the read operation of the column operation.

As described above, the semiconductor system 1 may replace the sixth column C6 of the first memory region 110 with the sixth column C6 of the repair region 150 when the sixth column C6 of the first memory region 110 is a failed column. The semiconductor system 1 may also replace the sixth column C6 of the third memory region 130 with the fourteenth column C14 of the third memory region 130 and may replace the fourteenth column C14 of the third memory region 130 with the fourteenth column C14 of the repair region 150, when the sixth column C6 of the third memory region 130 is a failed column.

In addition, the semiconductor system 1 may change an I/O path of the data DATA<1:N> from the first local I/O line LIO1 into the second local I/O line LIO2 and may change an I/O path of the data DATA<1:N> from the third local I/O line LIO3 into the repair I/O line RIO, when the sixth column C6 of the first memory region 110 is a failed column and the sixth column C6 of the third memory region 130 is a failed column.

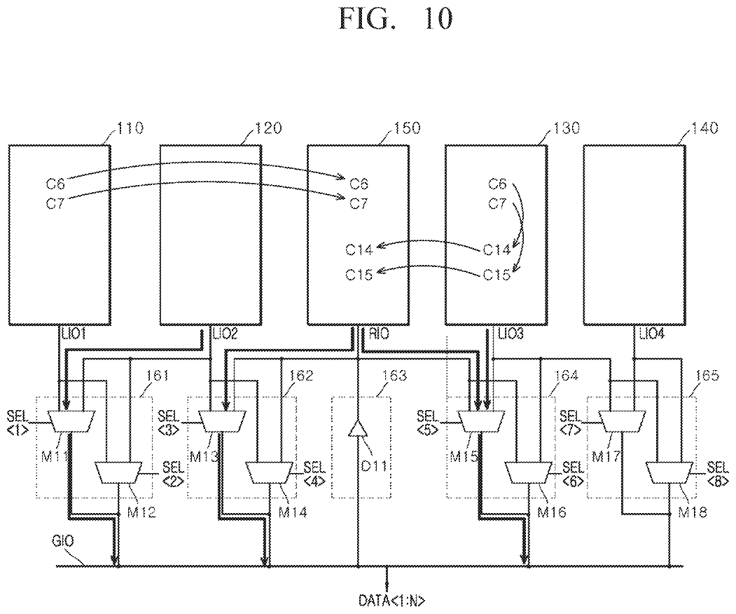

Next, the repair operation and the data I/O path change operation will be described hereinafter with reference to FIG. 10 based on an embodiment in which the sixth and seventh columns C6 and C7 of the first memory region 110 and the sixth and seventh columns C6 and C7 of the third memory region 130 are failed columns.

In the present example, the repair operation for the sixth column C6 of the first memory region 110 and the sixth column C6 of the third memory region 130 may be the same as the repair operation, described with reference to FIG. 9. Thus, the detailed descriptions of the repair operation for the sixth column C6 of the first memory region 110 and the sixth column C6 of the third memory region 130 will be omitted hereinafter.

The controller 10 may output the command CMD, the first failure address FADD1<1:K>, the third failure address FADD3<1:K>, and the address ADD<1:6> for performing the read operation of the column operation to the semiconductor device 20. The address ADD<1:6> may have a logic level combination that selects the seventh column C7 of the first memory region 110 and the seventh column C7 of the third memory region 130.

The repair circuit 200 may generate the seventh bit signal RADD<7> of the repair address RADD<1:64> based on the first failure address FADD1<1:K>. The repair circuit 200 may generate the fifteenth bit signal RADD<15> of the repair address RADD<1:64> based on the third failure address FADD3<1:K>. The repair circuit 200 may invert the first group of address ADD<1:3> and the second group of address ADD<4:6> based on the third failure address FADD3<1:K> to generate the fifteenth bit signal IADD3<15> of the third internal address IADD3<1:64>. The repair circuit 200 may generate the first and third selection signals SEL<1> and SEL<3> that are enabled by the first and third failure addresses FADD1<1:K> and FADD3<1:K> and may generate the fifth selection signal SEL<5> that is disabled by the first and third failure addresses FADD1<1:K> and FADD3<1:K>.

The repair region 150 may output the data DATA<1:N> stored in the seventh column C7, which is selected by the seventh bit signal RADD<7> of the repair address RADD<1:64>, to the repair I/O line RIO in response to the command CMD. The repair region 150 may output the data DATA<1:N> stored in the fifteenth column C15, which is selected by the fifteenth bit signal RADD<15> of the repair address RADD<1:64>, to the repair I/O line RIO in response to the command CMD.

The first data I/O circuit 161 may connect the second local I/O line LIO2 to the global I/O line GIO based on the first selection signal SEL<1> that is enabled during the read operation. The second data I/O circuit 162 may connect the repair I/O line RIO to the global I/O line GIO based on the third selection signal SEL<3> that is enabled during the read operation. The fourth data I/O circuit 164 may connect the repair I/O line RIO to the global I/O line GIO based on the fifth selection signal SEL<5> that is disabled during the read operation.

The data processing circuit 160 may output the data DATA<1:N> that is loaded on the second local I/O line LIO2 and the repair I/O line RIO to the global I/O line GIO based on the first, third, and fifth selection signals SEL<1>, SEL<3>, and SEL<5> during the read operation of the column operation.

As described above, the semiconductor system 1 may replace the sixth column C6 and the seventh column C7 of the first memory region 110 with the sixth column C6 and the seventh column C7 of the repair region 150 when the sixth column C6 and the seventh column C7 of the first memory region 110 are failed columns. The semiconductor system 1 may also replace the sixth column C6 and the seventh column C7 of the third memory region 130 with the fourteenth column C14 and the fifteenth column C15 of the third memory region 130 and may replace the fourteenth column C14 and the fifteenth column C15 of the third memory region 130 with the fourteenth column C14 and the fifteenth column C15 of the repair region 150, when the sixth column C6 and the seventh column C7 of the third memory region 130 are failed columns.

In addition, the semiconductor system 1 may change an I/O path of the data DATA<1:N> from the first local I/O line LIO1 into the second local I/O line LIO2 and may change an I/O path of the data DATA<1:N> from the third local I/O line LIO3 into the repair I/O line RIO, when the sixth column C6 and the seventh column C7 of the first memory region 110 are failed columns and the sixth column C6 and the seventh column C7 of the third memory region 130 are failed columns.

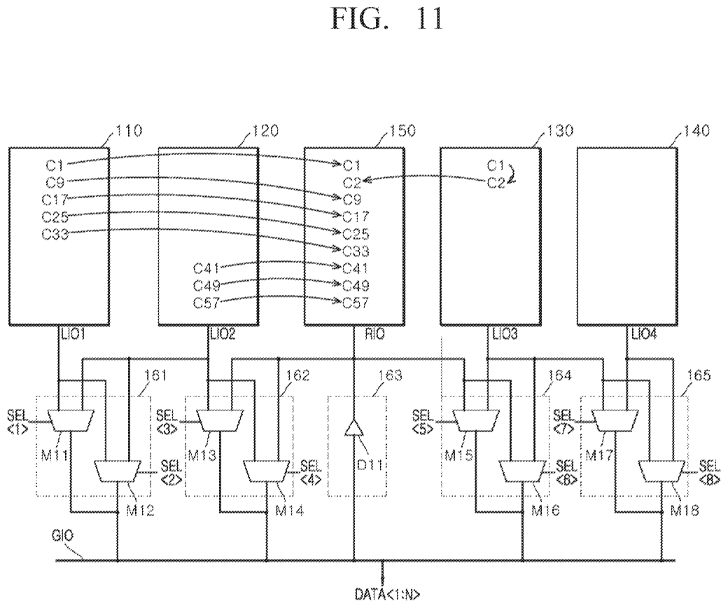

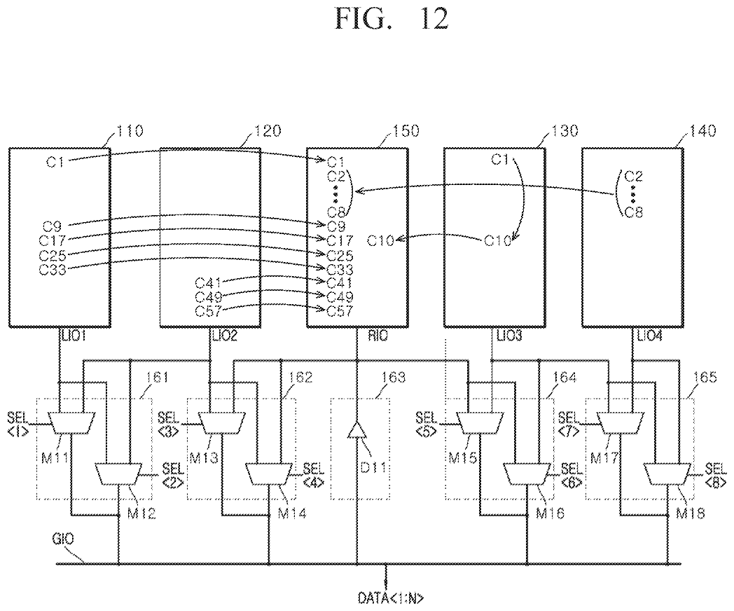

Operations of repairing failed columns that are included in various memory regions, which are performed during the read operation of the column operation of the semiconductor system 1, will be described hereinafter with reference to FIGS. 11 and 12.

First, the repair operation and the data I/O path change operation will be described hereinafter with reference to FIG. 11 based on an embodiment in which a plurality of columns C1, C9, C17, C25, and C33 of the first memory region 110, a plurality of columns C41, C49, and C57 of the second memory region 120, and the first column C1 of the third memory region 130 are failed columns.

In the present example, the repair operation for the columns C1, C9, C17, C25, and C33 of the first memory region 110 and the columns C41, C49, and C57 of the second memory region 120 is substantially the same as the repair operation for the failed columns of the first memory region 110, described with reference to FIGS. 8 to 10. Thus, the detailed descriptions of the repair operation for the columns C1, C9, C17, C25, and C33 of the first memory region 110 and the columns C41, C49, and C57 of the second memory region 120 will be omitted hereinafter.

The columns C1, C9, C17, C25, and C33 of the first memory region 110 and the columns C41, C49, and C57 of the second memory region 120 may be replaced with the columns C1, C9, C17, C25, C33, C41, C49, and C57 of the repair region 150.

Meanwhile, it may be difficult to replace the first column C1 of the third memory region 130 with the first column C1 of the repair region 150. Thus, the first column C1 of the third memory region 130 may be replaced with the second column C2 of the third memory region 130, and the second column C2 of the third memory region 130 may be replaced with the second column C2 of the repair region 150 during the column operation for the second column C2 of the third memory region 130.

As described above, the semiconductor system 1 may replace the columns C1, C9, C17, C25, and C33 of the first memory region 110 and the columns C41, C49, and C57 of the second memory region 120 with the columns C1, C9, C17, C25, C33, C41, C49, and C57 of the repair region 150 when the columns C1, C9, C17, C25, and C33 of the first memory region 110 and the columns C41, C49, and C57 of the second memory region 120 are failed columns. In addition, the semiconductor system 1 may replace the first column C1 of the third memory region 130 with the second column C2 of the third memory region 130 and may replace the second column C2 of the third memory region 130 with the second column C2 of the repair region 150 when the first column C1 of the third memory region 130 is a failed column.

Next, the repair operation and the data I/O path change operation will be described hereinafter with reference to FIG. 12 based on an embodiment in which a plurality of columns C1, C9, C17, C25, and C33 of the first memory region 110, a plurality of columns C41, C49, and C57 of the second memory region 120, the first column C1 of the third memory region 130, and a plurality of columns C2, C3, C4, C5, C6, C7, and C8 of the fourth memory region 140 are failed columns.

In the present example, the repair operation for the columns C1, C9, C17, C25, and C33 of the first memory region 110 and the columns C41, C49, and C57 of the second memory region 120 is substantially the same as the repair operation for the failed columns of the first memory region 110, described with reference to FIGS. 8 to 10. Thus, the detailed descriptions of the repair operation for the columns C1, C9, C17, C25, and C33 of the first memory region 110 and the columns C41, C49, and C57 of the second memory region 120 will be omitted hereinafter.

The columns C1, C9, C17, C25, and C33 of the first memory region 110, the columns C41, C49, and C57 of the second memory region 120, and the columns C2, C3, C4, C5, C6, C7, and C8 of the fourth memory region 140 may be replaced with the columns C1, C2, C3, C4, C5, C6, C7, C8, C9, C17, C25, C33, C41, C49, and C57 of the repair region 150.

Meanwhile, it may be difficult to replace the first column C1 of the third memory region 130 with the first column C1 of the repair region 150. Thus, the first column C1 of the third memory region 130 may be replaced with the tenth column C10 of the third memory region 130, and the tenth column C10 of the third memory region 130 may be replaced with the tenth column C10 of the repair region 150 during the column operation for the tenth column C10 of the third memory region 130.

As described above, the semiconductor system 1 may replace the columns C1, C9, C17, C25, and C33 of the first memory region 110, the columns C41, C49, and C57 of the second memory region 120, and the columns C2, C3, C4, C5, C6, C7, and C8 of the fourth memory region 140 with the columns C1, C2, C3, C4, C5, C6, C7, C8, C9, C17, C25, C33, C41, C49, and C57 of the repair region 150 when the columns C1, C9, C17, C25, and C33 of the first memory region 110, the columns C41, C49, and C57 of the second memory region 120, and the columns C2, C3, C4, C5, C6, C7, and C8 of the fourth memory region 140 are failed columns. In addition, the semiconductor system 1 may replace the first column C1 of the third memory region 130 with the tenth column C10 of the third memory region 130 and may replace the tenth column C10 of the third memory region 130 with the tenth column C10 of the repair region 150 when the first column C1 of the third memory region 130 is a failed column.

As described with reference to FIGS. 8 to 12, the semiconductor system 1, according to an embodiment, may invert a bit signal of an address to select a failed column and may perform a repair operation for replacing the failed column with a normal column of any one of a memory region and a repair region by using the address with the inverted bit signal. In addition, the semiconductor system 1 may internally invert bit signals of the address to select a failed column and may perform a repair operation for replacing the failed column with a normal column of any one of a memory region and a repair region by using the address with the inverted bit signals, thereby improving an efficiency of the repair operation. Moreover, the semiconductor system 1 may perform the repair operation for replacing a failed column of a memory region with a normal column of any one of the memory column and the repair region, thereby improving the reliability of data.

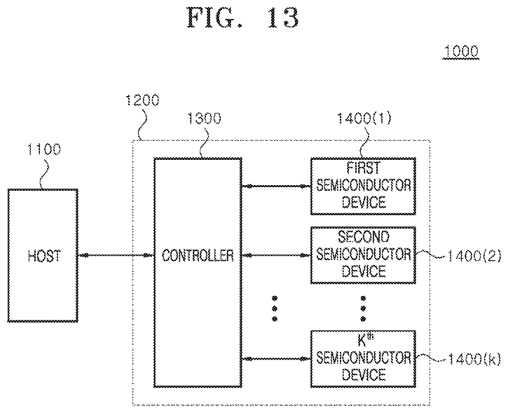

FIG. 13 is a block diagram, illustrating a configuration of an electronic system 1000, according to an embodiment, of the present disclosure. As illustrated in FIG. 13, the electronic system 1000 may include a host 1100 and a semiconductor system 1200.

The host 1100 and the semiconductor system 1200 may transmit signals to each other by using an interface protocol. The interface protocol used for communication between the host 1100 and the semiconductor system 1200 may include any one of various interface protocols such as a multi-media card (MMC), an enhanced small device interface (ESDI), an integrated drive electronics (IDE), a peripheral component interconnect-express (PCI-E), an advanced technology attachment (ATA), a serial ATA (SATA), a parallel ATA (PATA), a serial attached SCSI (SAS), and a universal serial bus (USB).

The semiconductor system 1200 may include a controller 1300 and semiconductor devices 1400(K:1). The controller 1300 may control the semiconductor devices 1400(K:1) such that the semiconductor devices 1400(K:1) perform the read operation and the write operation. Each of the semiconductor devices 1400(K:1) may invert bit signals of an address to select a failed column and may perform the repair operation for replacing the failed column with a normal column of any one of a memory region and a repair region by using the address with the inverted bit signal. Each of the semiconductor devices 1400(K:1) may internally invert bit signals of the address to select a failed column and may perform a repair operation for replacing the failed column with a normal column of any one of a memory region and a repair region by using the address with the inverted bit signals, thereby improving an efficiency of the repair operation.

The controller 1300 may include the controller 10 that is illustrated in FIG. 1. Each of the semiconductor devices 1400(K:1) may include the semiconductor device 20 illustrated in FIG. 1. In some embodiments, each of the semiconductor devices 1400(K:1) may include any one of a dynamic random access memory (DRAM), a phase change random access memory (PRAM), a resistive random access memory (RRAM), a magnetic random access memory (MRAM), and a ferroelectric random access memory (FRAM).

What is claimed is:

1. A semiconductor device comprising:
a core circuit configured to include first and second memory regions and a repair region, each of which has columns that are selected by a first internal address, a second internal address, and a repair address and configured to receive or output data through columns that are selected by the first internal address, the second internal addresses, and the repair address; and
a repair circuit configured to generate the first and second internal addresses by changing logic levels of first and second groups of addresses that are included in an address, to generate the repair address from first and second failure addresses, and to generate a selection signal to change an input/output (I/O) path of the data from the first and second failure addresses in order to repair a failed column of the columns.

2. The semiconductor device of claim 1, wherein the failed column among the columns is replaced with any one of normal columns that are included in the first and second memory regions and the repair region, based on first internal address, the second internal addresses, and the repair address.

3. The semiconductor device of claim 1,
wherein the first memory region, the second memory region, and the repair region have the same configuration that is comprised of a plurality of columns; and
wherein, when a failed column of the first memory region and a failed column of the second memory region have the same column address, the failed column of the first memory region is replaced with a column of the repair region with the same column address as the failed column of the first memory region and the failed column of the second memory region is replaced with another column of the columns that are included in the second memory region.

4. The semiconductor device of claim 1,
wherein each of the first and second groups of the addresses includes a plurality of bits; and
wherein the repair circuit inverts logic levels of the plurality of bits that are included in the first and second groups of the addresses to generate the first and second internal addresses in order to repair a failed column line of the columns.

5. The semiconductor device of claim 1, wherein the core circuit receives and outputs the data through the repair region and the other memory region except the memory region with the failed column, based on the selection signal.

6. The semiconductor device of claim 1, wherein the core circuit includes:
the first memory region configured to include a plurality of columns, one of which is selected by a command and the first internal address, and configured to receive or output the data through a first local I/O line;
the second memory region configured to include a plurality of columns, one of which is selected by the command and the second internal address, and configured to receive or output the data through a second local I/O line;
the repair region configured to include a plurality of columns, one of which is selected by the command and the repair address, and configured to receive or output the data through a repair I/O line; and
a data processing circuit configured to receive and output the data through a global I/O line, the first local I/O line, the second local I/O line, and the repair I/O line during a write operation and a read operation.

7. The semiconductor device of claim 6,
wherein the data processing circuit is configured to output the data inputted through the global I/O line to at least one of the first local I/O line, the second local I/O line, and the repair I/O line, which is selected by the selection signal during the write operation; and
wherein the data processing circuit is configured to output the data loaded on at least one of the first local I/O line, the second local I/O line, and the repair I/O line, which is selected by the selection signal through the global I/O line during the read operation.

8. The semiconductor device of claim 6, wherein the data processing circuit includes:
a first data I/O circuit configured to receive and output the data through the global I/O line, the first local I/O line, and the second local I/O line during the write operation and the read operation;
a second data I/O circuit configured to receive and output the data through the global I/O line, the second local I/O line, and the repair I/O line during the write operation and the read operation; and
a third data I/O circuit configured to output the data loaded on the global I/O line to the repair I/O line during the write operation.

9. The semiconductor device of claim 8,
wherein the first data I/O circuit is configured to output the data loaded on the global I/O line to any one of the first local I/O line and the second local I/O line, which is selected by the selection signal, during the write operation; and
wherein the first data I/O circuit is configured to output the data loaded on any one of the first local I/O line and the second local I/O line, which is selected by the selection signal, to the global I/O line during the read operation.

10. The semiconductor device of claim 8,
wherein the second data I/O circuit is configured to output the data loaded on the global I/O line to any one of the second local I/O line and the repair I/O line, which is selected by the selection signal, during the write operation; and
wherein second data I/O circuit is configured to output the data loaded on any one of the second local I/O line and the repair I/O line, which is selected by the selection signal, to the global I/O line during the read operation.

11. The semiconductor device of claim 1, wherein the repair circuit includes:
a selection signal generation circuit configured to generate the selection signal from the first and second failure addresses and the address;
a normal fuse circuit configured to compare the first and second failure addresses with the address and configured to generate the first and second internal addresses by changing logic levels of the first and second groups of addresses that are included in the address based on the comparison result; and
a repair fuse circuit configured to store the first and second failure addresses and configured to generate the repair address that is enabled when a logic level combination of the address is identical to a logic level combination of the first and second failure addresses.

12. The semiconductor device of claim 11, wherein the normal fuse circuit includes:
a normal fuse circuit configured to compare the first and second failure addresses with the address and configured to generate a first transfer address or a second transfer address by changing logic levels of the first and second groups of addresses that are included in the address based on the comparison result; and
an address decoder configured to decode the first and the second transfer addresses to generate the first and second internal addresses.

13. A semiconductor device comprising:
a core circuit configured to replace a first memory region with a failed column with any one of a second memory region and a repair region based on a first internal address, a second internal address, and a repair address to receive or output data; and
a repair circuit configured to generate the first and second internal addresses by changing logic levels of first and second groups of addresses that are included in an address, to generate the repair address from first and second failure addresses, and to generate a selection signal to change an input/output (I/O) path of the data from the first and second failure addresses in order to repair the failed column.

14. The semiconductor device of claim 13, wherein the failed column of the first memory region is replaced with any one of columns that are included in the first and second memory regions and the repair region, based on first internal address, the second internal addresses, and the repair address.

15. The semiconductor device of claim 13, wherein the failed column of the first memory region is replaced with any one of columns that are included in the repair region, based on the repair address and the selection signal.

16. The semiconductor device of claim 13,
wherein the first memory region, the second memory region, and the repair region have the same configuration that is comprised of a plurality of columns; and
wherein when a failed column of the first memory region and a failed column of the second memory region have the same column address, the failed column of the first memory region is replaced with a column of the repair region with the same column address as the failed column of the first memory region and the failed column of the second memory region is replaced with another column of the columns that are included in the second memory region.

17. The semiconductor device of claim 13,
wherein each of the first and second groups of the addresses includes a plurality of bits; and
wherein the repair circuit inverts logic levels of the plurality of bits that are included in the first and second groups of the addresses to generate the first and second internal addresses in order to repair a failed column line of the columns.

18. The semiconductor device of claim 13, wherein the core circuit receives and outputs the data through the repair region and the other memory region except the memory region with the failed column, based on the selection signal.

19. The semiconductor device of claim 13, wherein the core circuit includes:
the first memory region configured to include a plurality of columns, one of which is selected by a command and the first internal address, and configured to receive or output the data through a first local I/O line;
the second memory region configured to include a plurality of columns, one of which is selected by the command and the second internal address, and configured to receive or output the data through a second local I/O line;
the repair region configured to include a plurality of columns, one of which is selected by the command and the repair address, and configured to receive or output the data through a repair I/O line;
and a data processing circuit configured to receive and output the data through a global I/O line, the first local I/O line, the second local I/O line, and the repair I/O line during a write operation and a read operation.

20. The semiconductor device of claim 19,
wherein the data processing circuit is configured to output the data inputted through the global I/O line to at least one of the first local I/O line, the second local I/O line, and the repair I/O line, which is selected by the selection signal during the write operation; and
wherein the data processing circuit is configured to output the data loaded on at least one of the first local I/O line, the second local I/O line, and the repair I/O line, which is selected by the selection signal through the global I/O line during the read operation.

21. The semiconductor device of claim 19, wherein the data processing circuit includes:
a first data I/O circuit configured to receive and output the data through the global I/O line, the first local I/O line, and the second local I/O line during the write operation and the read operation;
a second data I/O circuit configured to receive and output the data through the global I/O line, the second local I/O line, and the repair I/O line during the write operation and the read operation; and
a third data I/O circuit configured to output the data loaded on the global I/O line to the repair I/O line during the write operation.

22. The semiconductor device of claim 21,
wherein the first data I/O circuit is configured to output the data loaded on the global I/O line to any one of the first local I/O line and the second local I/O line, which is selected by the selection signal, during the write operation; and
wherein the first data I/O circuit is configured to output the data loaded on any one of the first local I/O line and the second local I/O line, which is selected by the selection signal, to the global I/O line during the read operation.

23. The semiconductor device of claim 21,
wherein the second data I/O circuit is configured to output the data loaded on the global I/O line to any one of the second local I/O line and the repair I/O line, which is selected by the selection signal, during the write operation; and
wherein second data I/O circuit is configured to output the data loaded on any one of the second local I/O line and the repair I/O line, which is selected by the selection signal, to the global I/O line during the read operation.

24. The semiconductor device of claim 13, wherein the repair circuit includes:
a selection signal generation circuit configured to generate the selection signal from the first and second failure addresses and the address;
a normal fuse circuit configured to compare the first and second failure addresses with the address and configured to generate the first and second internal addresses by changing logic levels of the first and second groups of addresses that are included in the address based on the comparison result; and
a repair fuse circuit configured to store the first and second failure addresses and configured to generate the repair address that is enabled when a logic level combination of the address is identical to a logic level combination of the first and second failure addresses.

25. The semiconductor device of claim 24, wherein the normal fuse circuit includes:
a normal fuse circuit configured to compare the first and second failure addresses with the address and configured to generate a first transfer address or a second transfer address by changing logic levels of the first and second groups of addresses that are included in the address based on the comparison result; and
an address decoder configured to decode the first and the second transfer addresses to generate the first and second internal addresses.
